(19) United States
(12) Patent Application Publication
(10) Pub. No.: US 2020/0018910 A1
(43) Pub. Date: Jan. 16, 2020

(54) OPTICAL MODULE

(71) Applicant: Sumitomo Electric Industries,Ltd., Osaka-shi (JP)

(72) Inventors: Tomoya SAEKI, Osaka-shi (JP); Yasushi Fujimura, Osaka-shi (JP)

(73) Assignee: Sumitomo Electric Industries,Ltd, Osaka-Shi (JP)

(21) Appl. No.: 16/509,580

(22) Filed: Jul. 12, 2019

(30) Foreign Application Priority Data
Jul. 13, 2018 (JP) 2018-133540

(51) Int. Cl. G02B 6/42; G01J 9/02; G02B 6/12; G02B 6/02; H01S 5/024; H01S 5/06; H01S 5/022

(52) U.S. Cl. CPC G02B 6/4215; G01J 9/0246; G02B 6/12007; G02B 6/4214; G02B 2006/1215; H01S 5/02415; H01S 5/0612; H01S 5/02248; G02B 2006/12061; G02B 6/02076

(57) ABSTRACT

An optical module includes an LD that emits laser beam; a carrier that mounts the LD and thermistor thereon; a photodetector detecting the laser beam output from the LD; a TEC that mounts the carrier and the photodetector thereon; a chassis having a box-shape demarcated by walls that form a space for enclosing the LD, the TEC, and the photodetector therein, wherein at least of the walls has a window, and the thermistor arranged between the LD and the photodetector.

### TECHNICAL FIELD

The present disclosure relates to an optical module.

### BACKGROUND

Japanese Unexamined Patent Publication No. 2015-68854 describes an optical element and an optical monitor. The optical element includes an optical divider, two waveguides having optical path lengths different from each other, and an optical combining unit that combines light beams passing the two waveguides. The optical divider divides a light beam that enters the optical element, and enters the two divided light beams to the two waveguides. The optical combining unit combines the two light beams, and outputs two optical signals each having light intensity different from the light intensity of the input light beam that enters the optical element and having a phase difference between the two optical signals.

Japanese Unexamined Patent Publication No. 2017-135252 describes a light emitting module including a wavelength tunable laser diode (LD). The wavelength tunable LD outputs an output light beam from one light emitting surface and an output light beam from the other light emitting surface. On the optical path of the output light beam from the one light emitting surface, a collimating lens, a polarized beam splitter, and a reflection filter are provided. On the optical path of the output light beam from the other light emitting surface, a collimating lens, a polarization optical system, a half mirror, and an etalon filter are provided. The etalon filter functions as a wavelength detection unit that detects an output light beam.

### SUMMARY

An optical module according to an aspect includes a carrier mounted with a wavelength tunable laser element configured to emit a laser light beam, and a temperature detection element; an optical detection element configured to detect the laser light beam output from the wavelength tunable laser element; a temperature regulation element mounted with the carrier and the optical detection element; and a housing accommodating the temperature regulation element, and having a window part through which the laser light beam is output. The temperature detection element is disposed between the wavelength tunable laser element and the optical detection element.

### BRIEF DESCRIPTION OF THE DRAWINGS

FIG. 1 is a plan view showing the internal structure of an optical module according to an embodiment of the present disclosure;

FIG. 2 is a sectional side view of the optical module in FIG. 1;

FIG. 3 is a diagram schematically showing the cross section of a wavelength tunable laser element of the optical module in FIG. 1;

FIG. 4 is a diagram schematically showing the configuration of an optical detection element of the optical module in FIG. 1;

FIG. 5 is a plan view schematically showing the disposition of the components of the optical module in FIG. 1;

FIG. 6 is a sectional side view schematically showing the disposition of the components of the optical module in FIG. 1;

FIG. 7 is a plan view schematically showing the disposition of the components of an optical module of a reference example; and

FIG. 8 is a vertical cross sectional view schematically showing the disposition of the components of the optical module of the reference example.

### DETAILED DESCRIPTION

In the optical module, it is demanded to reduce the size. The above-described wavelength tunable laser element, such as a wavelength tunable LD, is possibly a heat generating source in the optical module. Therefore, the optical module includes a TEC (a temperature regulation element) that regulates the temperature of the wavelength tunable laser element and a temperature detection element, such as a thermistor. In this optical module, the temperature detection element disposed at the position adjacent to the wavelength tunable laser element detects temperatures, and the TEC controls the temperature corresponding to the temperature detected by the temperature detection element. Thus, the temperature of the wavelength tunable laser element is made constant, and the stable operation of the wavelength tunable laser element is achieved.

However, in the inside of the optical module, a temperature bias occurs depending on the distance from the wavelength tunable laser element that is possibly a heat generating source. The bias is further expanded due to the influence of the temperature of an external environment. Therefore, for example, in the state in which the wavelength tunable laser element excessively generates heat, the TEC performs cooling such that the wavelength tunable laser element is restrained from excessively generating heat. Thus, at the position apart from the wavelength tunable laser element, the state is an excessive cooling state, and the temperature sometimes drops. In the case in which the temperature of the external environment is lower than the temperature set to the TEC, the temperature bias is further increased.

As the optical detection element, such as the above-described wavelength detection unit, a silicon-based wavelength locker chip is sometimes used. The optical detection element is sometimes disposed at the position apart from the wavelength tunable laser element and the temperature detection element. In the case in which the optical detection element is thus disposed at the position apart from the wavelength tunable laser element and the temperature detection element, a temperature bias is present as described above, and hence the deviation between the temperature detected by the temperature detection element and the actual temperature of the optical detection element is likely increased. In the case in which the optical detection element is the above-described wavelength locker chip, when the deviation between the temperatures is large as described above, the dependence of the refractive index of silicon on the temperature works to possibly cause the variation in the characteristics. Since the variation in the characteristics of the wavelength locker chip is possibly a cause of a shift in the oscillation wavelength of the wavelength tunable laser element, the variation is likely to interfere with the stable operation of the wavelength tunable laser element.

An object of the present disclosure is to provide an optical module that can achieve a reduction in size and can stably operate a wavelength tunable laser element.

According to the present disclosure, a reduction in size can be achieved, and the wavelength tunable laser element can be stably operated.

### Description of an Embodiment of the Present Disclosure

First, the content of an embodiment of the present disclosure will be described in list. An optical module according to an embodiment includes a chip carrier mounted with a wavelength tunable laser element configured to emit a laser light beam and a temperature detection element, an optical detection element configured to detect the laser light beam output from the wavelength tunable laser element, a temperature regulation element mounted with the chip carrier and the optical detection element, and a housing accommodating the temperature regulation element, and having a window part through which the laser light beam is output. The temperature detection element is disposed between the wavelength tunable laser element and the optical detection element.

This optical module includes the chip carrier mounted with the wavelength tunable laser element and the temperature detection element, the optical detection element, and the temperature regulation element mounted with the chip carrier and the optical detection element. The temperature detection element is disposed between the wavelength tunable laser element and the optical detection element. The temperature detection element is disposed between the wavelength tunable laser element and the optical detection element, and hence the optical detection element can be disposed at the position adjacent to the wavelength tunable laser element and the temperature detection element.

Therefore, the deviation between the temperature detected by the temperature detection element and the actual temperature of the optical detection element can be made small, and hence the variation in the characteristics of the optical detection element due to temperature dependence can be restrained. Therefore, the shift in the oscillation wavelength of the wavelength tunable laser element can be restrained, and hence the wavelength tunable laser element can be stably operated. The optical detection element is disposed at the position adjacent to the wavelength tunable laser element and the temperature detection element, and hence the elements in the inside of the optical module can be compactly disposed. Therefore, the elements are compactly disposed, and hence a reduction in the size of the optical module can be achieved.

The optical detection element may be made up of a silicon-based semiconductor material. In this case, as described above, the optical detection element is disposed at the position adjacent to the wavelength tunable laser element and the temperature detection element, and hence the deviation between the temperatures is restrained, and the variation in the characteristics of the refractive index of silicon in the optical detection element can be reduced. Therefore, even though the optical detection element and the wavelength tunable laser element are disposed on one temperature regulation element, the wavelength tunable laser element can be stably operated.

The above-described optical module may further include a beam splitter configured to direct the laser light beam output from the wavelength tunable laser element to the direction opposite to the output direction of the laser light beam. In this case, the laser light beam output from the wavelength tunable laser element is directed to the direction opposite to the output direction by the beam splitter. The laser light beam is directed to the direction opposite to the output direction, and hence the region occupied by the optical path of the laser light beam in the inside of the optical module can be made small. Thus, the optical module can be further reduced in size. The laser light beam directed to the opposite direction by the beam splitter is input to the optical detection element, and hence the optical detection element can be disposed at the position adjacent to the wavelength tunable laser element. Therefore, the position of the optical detection element can be brought close to the position of the wavelength tunable laser element.

An isolator located between the wavelength tunable laser element and the beam splitter may be further included. In this case, the region between the wavelength tunable laser element and the beam splitter can be effectively used as a region where the isolator is disposed.

### Detail of the Embodiment of the Disclosure of the Present Application

In the following, a specific example of the optical module according to the disclosure of the present application will be described with reference to the drawings. Note that the present disclosure is not limited to the examples below, and aims to include all modifications in the scope equivalent to claims. In the description of the drawings, the same or corresponding components are designated with the same reference signs, and the duplicate description is appropriately omitted. The drawings are sometimes partially simplified or exaggerated for easy understanding, and dimensions and ratios, for example, are not limited to those described on the drawings.

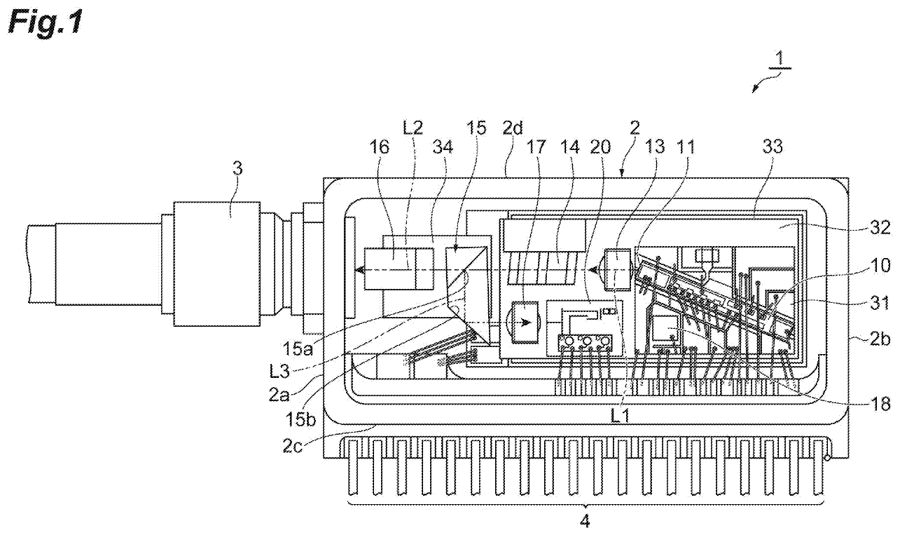

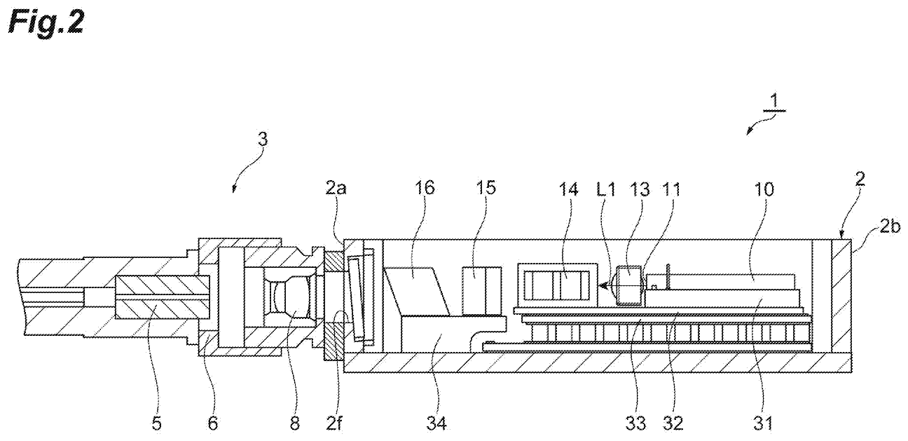

FIG. 1 is a diagram showing the internal structure of an optical module 1 according to an embodiment. FIG. 2 is a diagram showing the cross section of the optical module 1. As shown in FIGS. 1 and 2, the optical module 1 includes a housing 2 (chassis) having a first face 2a located on the front side of the housing 2, a second face 2b located on the rear side of the housing 2, and a pair of side faces 2c and 2d connecting the first face 2a to the second face 2b. In the internal space of the housing 2, the components of the optical module 1 are mounted, and the housing 2 is air-tightly sealed with a cover part. The housing 2 has a box-shaped demarcated by walls that form a space for enclosing a LD, a TEC and a photodetector therein.

The optical module 1 includes a wavelength tunable laser element 10 that is a semiconductor laser. The wavelength tunable laser element 10 is a wavelength tunable laser diode (LD). The wavelength tunable laser element 10 is mounted on the internal space of the housing 2 defined by the first face 2a, the second face 2b, and the pair of side faces 2c and 2d. The wavelength tunable laser element 10 emits a laser light beam L1 from a front face 11 that is one light emitting surface.

On the first face 2a of the housing 2, an optical output port 3 is provided. On the side face 2c of the housing 2, the optical module 1 includes an electrical connecting terminal 4, such as a lead pin, that electrically communicates with the outside of the optical module 1. Signals handled at the electrical connecting terminal 4 are substantially DC signals that are power supply signals, bias signals, or GND signals, for example. The side faces 2c and 2d extend from the first face 2a provided with the optical output port 3 to the rear side in parallel with each other. For example, the optical module 1 has no electrical connecting terminal 4 on the second face 2b and the side face 2d, and the second face 2b and the side face 2d are flat having no externally protruding portions. The second face 2b and the side face 2d having no externally protruding portion are provided as described above, and hence the size of the housing 2 can be restrained, contributing to a reduction in the size of the optical module 1.

In addition to the wavelength tunable laser element 10, the optical module 1 includes a first lens 13, an isolator 14, a beam splitter 15, a beam shifter 16, a second lens 17, a temperature detection element 18, and an optical detection element (photodetector) 20. The optical module 1 further includes a chip carrier 31 mounted with the wavelength tunable laser element 10 and the temperature detection element 18, a first base 32 mounted with the first lens 13, the isolator 14, the second lens 17, the optical detection element 20, and the chip carrier 31, a TEC 33 (a temperature regulation element) mounted with the first base 32, and a second base 34 mounted with the beam splitter 15 and the beam shifter 16.

The housing 2 accommodates the TEC 33. The wavelength tunable laser element 10 is disposed, for example, in the center in the width direction of the housing 2 and on the rear side of the housing 2 in the longitudinal direction (on the opposite side of the optical output port 3). On the optical path of the laser light beam L1 to be output from the wavelength tunable laser element 10, the first lens 13, the isolator 14, and the beam splitter 15 are provided. The wavelength tunable laser element 10 has a shape extending long in a certain direction. The wavelength tunable laser element 10 is obliquely mounted to the optical axis of the first lens 13 at a significant angle that is not 0° or 90°.

The wavelength tunable laser element 10 is obliquely disposed such that the wavelength tunable laser element 10 is directed to the temperature detection element 18 side from the optical axis of the laser light beam L. The tilt angle of the wavelength tunable laser element 10 to the optical axis of the laser light beam L1 is an angle of 20° or more and 60° or less, for example. Although the laser light beam L1 is output in parallel to the optical axis of the first lens 13, the wavelength tunable laser element 10 is obliquely disposed to the optical axis of the laser light beam L1, and hence the laser light beam L is restrained from returning to the wavelength tunable laser element 10. That is, the above-described tilt angle is an angle of 20° or more and 60° or less, and hence the laser light beam L1 output from the wavelength tunable laser element 10 can be restrained from reflecting and returning to the wavelength tunable laser element 10. The configuration of the wavelength tunable laser element 10 will be described later in detail.

The first lens 13 is a collimating lens that converts the laser light beam L1 from the wavelength tunable laser element 10 from a divergent light beam into collimated light. The isolator 14 passes the laser light beam L1 from the first lens 13, and the beam splitter 15 splits the laser light beam L1. The beam splitter 15 has a first reflection plane 15a provided with a beam splitter film that transmits and reflects the laser light beam L1 and a second reflection plane 15b provided with a total reflection film.

The first reflection plane 15a and the second reflection plane 15b are both inclined to the optical axis of the laser light beam L1 from the wavelength tunable laser element 10, and the tilt angles of the first reflection plane 15a and the second reflection plane 15b to the optical axis of the laser light beam L1 are both precisely determined. The beam splitter 15 forms a truncated pyramid shape in which a triangular prism having a right triangular shape in a planar view is removed from an element in a rectangular shape in a planar view. As described above, the beam splitter 15 forms a truncated pyramid shape from which a triangular prism is removed, and hence the cost of the beam splitter 15 can be reduced.

A laser light beam L2 transmitted through the first reflection plane 15a of the beam splitter 15 is coupled to the beam shifter 16, and a laser light beam L3 reflected off the first reflection plane 15a is reflected off the second reflection plane 15b, directed to the opposite direction (on the rear side) to the output direction (on the front side) of the laser light beam L1, and coupled to the second lens 17. That is, the beam splitter 15 has the function that turns back the laser light beam L1 at an angle of 180°. The beam shifter 16 is disposed between the beam splitter 15 and the optical output port 3, and provided to absorb the difference of the horizontal level of the optical axis of the laser light beam L2.

The beam shifter 16 complements the horizontal level between the optical axis of the laser light beam L2 output from the beam splitter 15 and the optical output port 3. The beam shifter 16 is disposed between the beam splitter 15 and the optical output port 3, and hence the horizontal level of the optical axis of the laser light beam L2 going from the beam splitter 15 to the optical output port 3 can be adjusted. The housing 2 has a window 2f on the first face 2a through which the laser light beam L2 is output, and the laser light beam L2 is emitted to the outside of the optical module 1 through the window 2f and the optical output port 3. On the other hand, the laser light beam L3 reflected off the first reflection plane 15a is collected at the second lens 17, and enters the optical detection element 20.

The temperature detection element 18 is a thermistor that detects temperatures, and the TEC 33 controls the temperatures of the wavelength tunable laser element 10 and the optical detection element 20 corresponding to the temperature detected by the temperature detection element 18. The optical detection element 20 is a wavelength detection element that detects the wavelength of the laser light beam L1 output from the wavelength tunable laser element 10.

The optical detection element 20 is made up of a silicon-based semiconductor material, for example, and is a wavelength locker chip having a spectrometer function in the inside. The optical detection element 20 may be made up of an InP (Indium Phosphide)-based semiconductor material, and may include a light receiving element having a light receiving function, for example. The configuration of the optical detection element 20 will be described later in detail.

The optical output port 3 includes a pigtail component 5 incorporating a polarization maintaining optical fiber with stubs, a holder 6 holding the pigtail component 5, and a lens holder 8 holding a lens. The optical output port 3 is in pigtail connection to the polarization maintaining optical fiber with the pigtail component 5. The alignment of the pigtail component 5 in the optical axis direction is achieved by penetration welding, for example. The optical alignment of the pigtail component 5 is performed by penetrating the pigtail component 5 through the holder 6. The pigtail component 5 is fixed to the holder 6 by YAG welding, and hence alignment can be performed highly accurately with high strength. The holder 6 may be fixed to the lens holder 8, and the lens holder 8 may be fixed to the housing 2 by fillet welding.

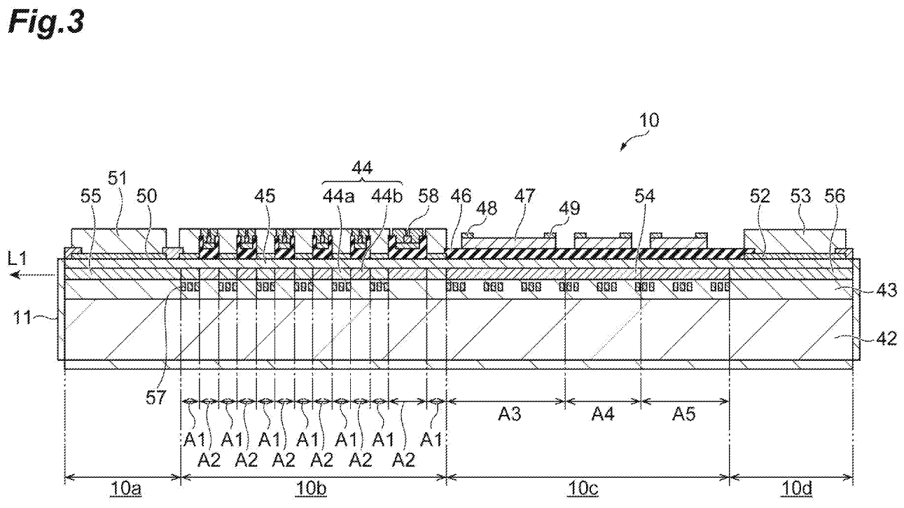

Next, the wavelength tunable laser element 10 will be described in detail with reference to FIG. 3. FIG. 3 is a diagram showing the cross sectional structure of the wavelength tunable laser element 10. The wavelength tunable laser element 10 includes an SG-DFG 10b (Sampled Grating Distributed FeedBack), a CSG-DBR 10c (Chirped Sampled Grating Distributed Bragg Reflector), and SOAs 10a and 10d (Semiconductor Optical Amplifier).

The SG-DFG 10b and the CSG-DBR 10c form a resonator. This resonator selects one wavelength. The SG-DFG 10b has a gain and a sampled grating. The CSG-DBR 10c has a sampled grating. The SG-DFG 10b has a stacked structure in which a lower cladding layer 43 including the sampled grating, an optical waveguide layer 44, and an upper cladding layer 45 are stacked on a substrate 42. The CSG-DBR 10c has a stacked structure in which a lower cladding layer 43 including the sampled grating, an optical waveguide layer 54, the upper cladding layer 45, an insulating film 46, and a plurality of heaters 47 are stacked on the substrate 42.

The heaters 47 are individually provided with a power supply electrode 48 and a ground electrode 49. The SOA 10a has a structure in which the lower cladding layer 43, an active layer 55, the upper cladding layer 45, a contact layer 50, and an electrode 51 are stacked on the substrate 42. The SOA 10d has a stacked structure in which the lower cladding layer 43, an active layer 56, the upper cladding layer 45, a contact layer 52, and an electrode 53 are stacked on the substrate 42.

The optical waveguide layer 44 has a structure in which an active layer 44a and a waveguide layer 44b are alternately arranged along the light propagation direction. On the upper cladding layer 45 located on the waveguide layer 44b, a heater 58 is provided through the insulating film 46.

On the SG-DFG 10b and the CSG-DBR 10c, a sampled grating (SG) 57 that is a sampled diffraction grating is formed in the lower cladding layer 43, the SGs 57 being discretely formed at a predetermined spacing. The SG-DFG 10b has a gain region A1 and a modulation region A2. In the gain region A1, the carrier is injected from the electrode disposed above to the active layer 44a. Thus, the SG-DFG 10b has an optical gain.

On the other hand, in the modulation region A2, the heater 58 is included in the upper part, and the temperature of the waveguide layer 44b is changed by giving electric power to the heater 58. The SG 57 is configured of regions having the diffraction grating and a region having no diffraction grating between the regions, showing an optical gain spectrum in which a plurality of peaks appears at regular intervals in the gain regions A1 and the modulation regions A2 as a whole. Changing the electric power that is given to the heater 58 to change the refractive index of the waveguide layer 44b, and hence the wavelength and interval of the peak can be changed.

The CSG-DBR 10c has three segments A3, A4, and A5. The segments A3, A4, and A5 each have the heater 47 and the SG 57 independently driven. With the operation of the SG 57, the CSG-DBR 10c shows a reflection spectrum in which a plurality of peaks discretely appears. The refractive index of the optical waveguide layer 54 is changed by the electric power given to the heater 47, and hence the wavelength and interval of the peak can be changed similarly to the description above. In order to set one peak wavelength that is selected to a predetermined wavelength, the temperature of the entire wavelength tunable laser element 10 is adjusted by the TIEC 33.

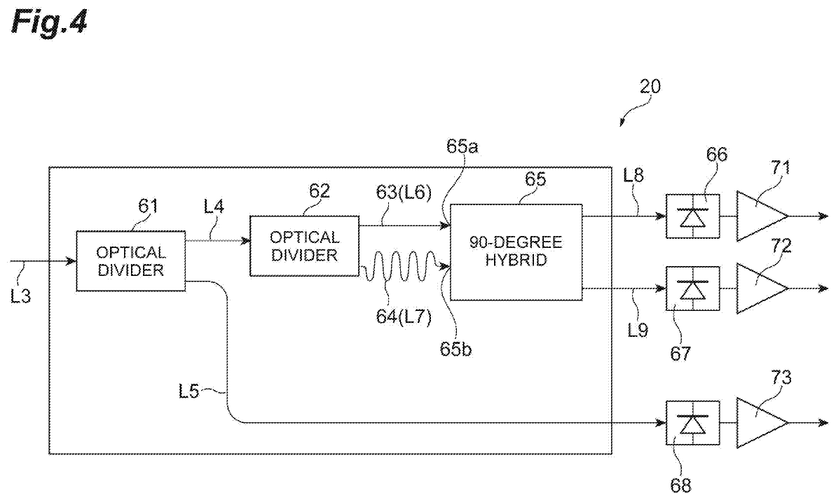

Next, the optical detection element 20 will be described in detail with reference to FIG. 4. FIG. 4 is a diagram schematically showing the configuration of the optical detection element 20. As described above, the optical detection element 20 is a wavelength monitor that detects the wavelength of the laser light beam L1 from the wavelength tunable laser element 10. The optical detection element 20 includes, for example, a first optical divider 61, a second optical divider 62, a first waveguide 63, a second waveguide 64, a 90-degree hybrid 65, a first light receiving element 66, a second light receiving element 67, a third light receiving element 68, and TIAs 71 to 73 (trans-impedance amplifiers).

The first optical divider 61 divides the laser light beam L3 input to the optical detection element 20 through the second lens 17 into two beams. One light beam L4 divided by the first optical divider 61 enters the second optical divider 62, and another light beam L5 divided by the first optical divider 61 enters the third light receiving element 68. The third light receiving element 68 subjects the incident light beam L5 to photoelectric conversion, and an electric current signal obtained through photoelectric conversion by the third light receiving element 68 is converted into a voltage signal by the TIA 73 provided on a PCB, for example, outside the optical module 1. From the first optical divider 61 to the third light receiving element 68, an optical element, such as a wavelength filter, is not disposed, and hence the light intensity of the input light beam to the optical detection element 20 can be detected with no wavelength dependence by detecting the output from the TIA 73.

In two light beams L6 and L7 to be output from the second optical divider 62, the light beam L6 enters one input end 65a of the 90-degree hybrid 65 via the first waveguide 63. In the two light beams L6 and L7 to be output from the second optical divider 62, the light beam L7 enters another input end 65b of the 90-degree hybrid 65 via the second waveguide 64. The first waveguide 63 and the second waveguide 64 have optical path lengths different from each other. Therefore, between the first waveguide 63 and the second waveguide 64, a propagation delay difference (a phase difference) is set. With the phase difference between the two waveguides 63 and 64, the filter characteristics are achieved in which the transmission intensity is periodically changed to the wavelength.

That is, the phase difference between the two waveguides 63 and 64 determines the FSR (Free Spectral Range) of the optical filter. The first waveguide 63 and the second waveguide 64 have the function that converts frequency fluctuations into light intensity fluctuations. The difference between the optical length of the first waveguide 63 and the optical length of the second waveguide 64 is ΔL, the refractive index of the first waveguide 63 and the second waveguide 64 is n, and the velocity of light is c, and then the FSR can be expressed by the following equation

FSR=c/(n×ΔL).

The 90-degree hybrid 65 generates two filter characteristics in which the phase relationship is shifted by π/2 to the wavelength axis. One light beam L8 to be output from the 90-degree hybrid 65 enters the first light receiving element 66, and another light beam L9 to be output from the 90-degree hybrid 65 enters the second light receiving element 67. The first light receiving element 66 subjects the light beam L8 to photoelectric conversion, and an electric current signal obtained through photoelectric conversion by the first light receiving element 66 is input to the TIA 71 provided on the PCB, for example, outside the optical module 1.

The TIA 71 converts the electric current signal output from the first light receiving element 66 into a voltage signal. The second light receiving element 67 subjects the light beam L9 to photoelectric conversion, and an electric current signal obtained through photoelectric conversion by the second light receiving element 67 is input to the TIA 72. The TIA 72 converts the electric current signal output from the second light receiving element 67 into a voltage signal. In the outputs of the TIA 71 and the TIA 72, monitoring one or both of the outputs can monitor the amount of fluctuations to a given wavelength.

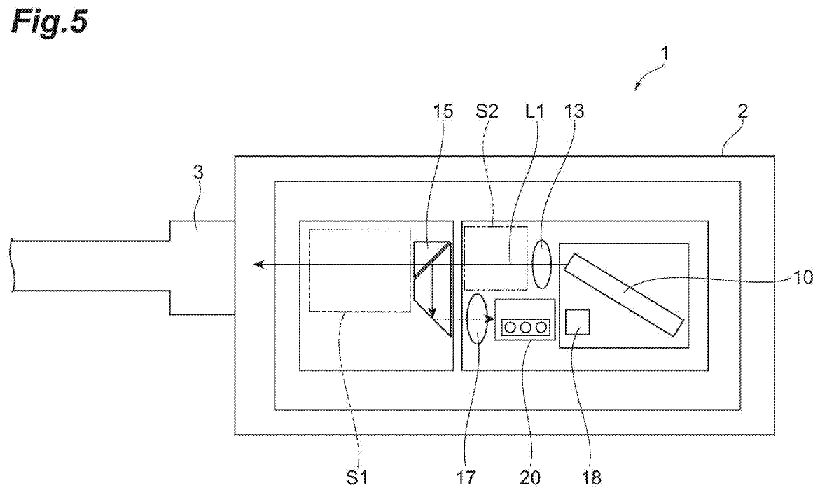

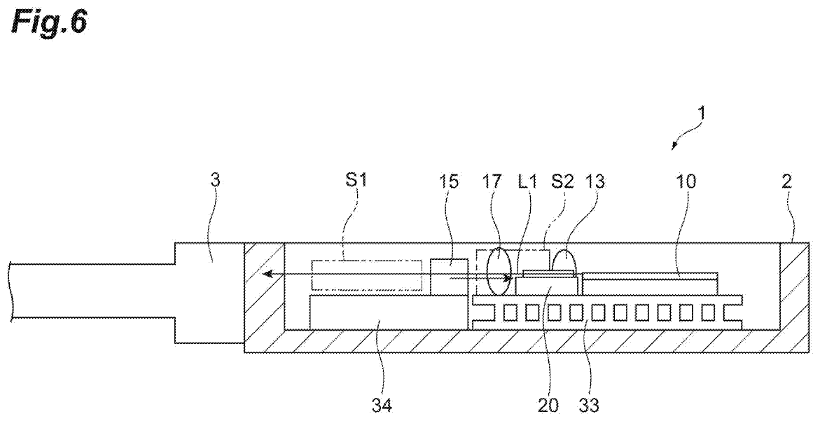

The disposition of the components of the optical module 1 thus configured will be described in detail with reference to FIGS. 5 and 6. FIG. 5 is a plan view schematically showing the internal structure of the optical module 1. FIG. 6 is a sectional side view schematically showing the internal structure of the optical module 1. Note that in FIGS. 5 and 6, the components of the optical module 1 are partially omitted. As described above, the wavelength tunable laser element 10 is disposed on the rear side of the optical module 1 (on one side of the housing 2 in the longitudinal direction), and the first lens 13 and the beam splitter 15 are provided on the optical path of the laser light beam L1 from the wavelength tunable laser element 10. The first lens 13 is provided on the front side of the wavelength tunable laser element 10 (on another side of the housing 2 in the longitudinal direction), and the beam splitter 15 is provided on the front side of the first lens 13.

Between the beam splitter 15 and the wavelength tunable laser element 10, the first lens 13, the second lens 17, the temperature detection element 18, and the optical detection element 20 are disposed. The laser light beam L1 to be emitted from the wavelength tunable laser element 10 and the first lens 13 are located on one side of the optical module 1 in the width direction, and the second lens 17, the optical detection element 20, and the temperature detection element 18 are located on the other side of the optical module 1 in the width direction.

Between the beam splitter 15 and the optical output port 3, a vacant region S1 is provided, and the beam shifter 16 is disposed in the vacant region S1. Between the beam splitter 15 and the first lens 13, a vacant region S2 is provided, and the isolator 14 is disposed in the vacant region S2. Between the second lens 17 and the temperature detection element 18, the optical detection element 20 is disposed. Between the optical detection element 20 and the wavelength tunable laser element 10, the temperature detection element 18 is disposed.

The wavelength tunable laser element 10 is disposed at the position adjacent to the temperature detection element 18, and the temperature detection element 18 is disposed at the position adjacent to the optical detection element 20. Here, the term “disposed at the position adjacent to” means the state in which two elements are adjacent to each other and no other element (an optical element and any other element) is present between these two elements. That is, between the wavelength tunable laser element 10 and the temperature detection element 18 and between the temperature detection element 18 and the optical detection element 20, no other element is present. However, connecting members, such as wires, are sometimes present.

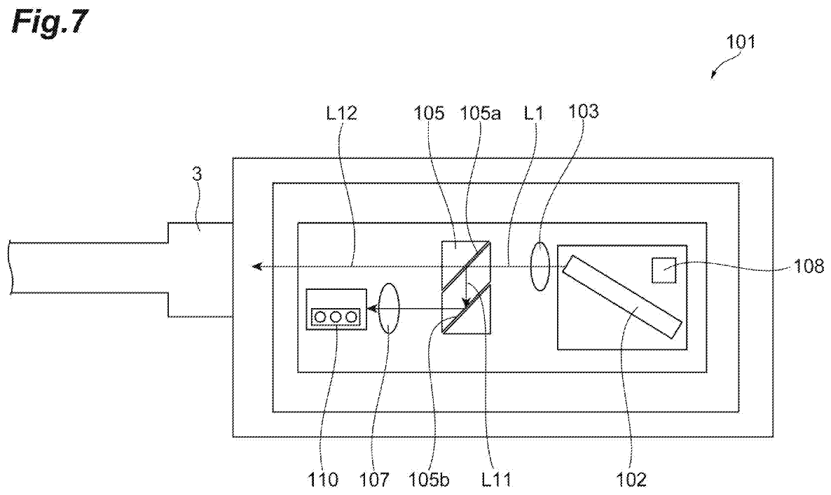

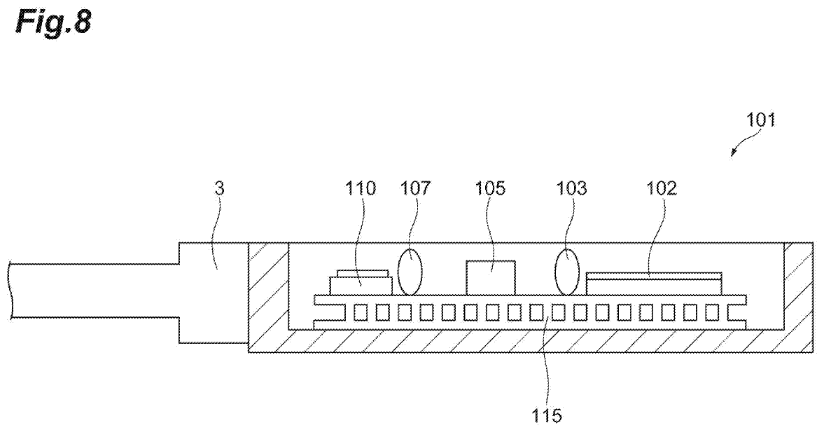

The disposition of the components of an optical module 101 of a reference example that is different from the optical module 1 will be described with reference to FIGS. 7 and 8. FIG. 7 is a plan view schematically showing the internal structure of the optical module 101. FIG. 8 is a sectional side view schematically showing the internal structure of the optical module 101. The optical module 101 includes a wavelength tunable laser element 102 and a first lens 103, and the functions of the wavelength tunable laser element 102 and the first lens 103 are similar to the functions of the wavelength tunable laser element 10 and the first lens 13 described above. In the optical module 101, the positions of the wavelength tunable laser element 102 and the first lens 103 are similar to the positions of the wavelength tunable laser element 10 and the first lens 13 of the optical module 1.

The optical module 101 includes a beam splitter 105 that does not turn back a laser light beam L1, instead of the beam splitter 15 that turns back the laser light beam L1 at an angle of 180°. The beam splitter 105 has a first reflection plane 105a that transmits and reflects the laser light beam L1 and a second reflection plane 105b that totally reflects off a light beam L11 reflected off the first reflection plane 105a. A light beam L12 transmitted through the first reflection plane 105a is directed to an optical output port 3, and the light beam L11 reflected off the first reflection plane 105a is reflected off the second reflection plane 105b, and directed to the direction in parallel with the light beam L12.

On the optical path of the light beam L11 reflected off the second reflection plane 105b, a second lens 107 and an optical detection element 110 are provided. The light beam L11 reflected off the second reflection plane 105b is collected at the second lens 107, and enters the optical detection element 110. The functions of the second lens 107 and the optical detection element 110 are the same as the functions of the second lens 17 and the optical detection element 20 described above.

In the optical module 101, a temperature detection element 108 is provided on the opposite side of the wavelength tunable laser element 102 where the first lens 103 is provided. The function of the temperature detection element 108 is similar to the function of the temperature detection element 18 described above. The optical module 101 includes a TEC 115 mounted with the wavelength tunable laser element 102, the first lens 103, the beam splitter 105, the second lens 107, the temperature detection element 108, and the optical detection element 110. The position of the temperature detection element 108 in the optical module 101 is located on the rear side of the wavelength tunable laser element 102 and close to the rear end of the optical module 101. On the other hand, the position of the optical detection element 110 in the optical module 101 is located near the optical output port 3 and close to the front end of the optical module 101.

In the inside of the optical module 101, a temperature bias occurs depending on the distance from the wavelength tunable laser element 102 that is possibly a heat generating source; for example, the temperature is high at a position close to the wavelength tunable laser element 102, whereas the temperature is low at a position away from the wavelength tunable laser element 102. This bias is expanded due to the influence of the temperature of the external environment, and a reduction in the thickness of the housing 2 is requested nowadays, possibly making the temperature bias further noticeable.

Therefore, for example, in the state in which the wavelength tunable laser element 102 excessively generates heat, the TEC 115 performs cooling such that the wavelength tunable laser element 102 is restrained from excessively generating heat. Thus, at the position apart from the wavelength tunable laser element 102, the state is an excessive cooling state, and the temperature sometimes drops. In the case in which the temperature of an external environment is lower than the temperature set to the TEC 115, the temperature bias is further increased.

Therefore, as described above, in the case in which the optical detection element 110 is disposed at the position apart from the wavelength tunable laser element 102 and the temperature detection element 108, the deviation between the temperature detected by the temperature detection element 108 and the actual temperature of the optical detection element 110 is likely increased due to the temperature bias. When the deviation between the temperatures is large as described above, the dependence of the refractive index of silicon in the optical detection element 110 on the temperature works to cause the variation in the characteristics, and the variation in the characteristics is possibly a cause of a shift in the oscillation wavelength of the wavelength tunable laser element 102. Therefore, the deviation between the temperatures is likely to interfere with the stable operation of the wavelength tunable laser element 102. In contrast to this, the optical module 1 according to the embodiment can restrain the problems.

In the following, the operation and the effect obtained from the optical module 1 according to the embodiment will be described in detail. As shown in FIGS. 1 and 2, the optical module 1 includes the chip carrier 31 mounted with the wavelength tunable laser element 10 and the temperature detection element 18, the optical detection element 20, and the TEC 33 mounted with the chip carrier 31 and the optical detection element 20. The temperature detection element 18 is disposed between the wavelength tunable laser element 10 and the optical detection element 20. The temperature detection element 18 is disposed between the wavelength tunable laser element 10 and the optical detection element 20, and hence the optical detection element 20 can be disposed at the position adjacent to the wavelength tunable laser element 10 and the temperature detection element 18.

Therefore, the deviation between the temperature detected by the temperature detection element 18 and the actual temperature of the optical detection element 20 can be made small, and hence the variation in the characteristics of the optical detection element 20 due to temperature dependence can be reduced. Therefore, a shift in the oscillation wavelength of the wavelength tunable laser element 10 can be restrained, and hence the wavelength tunable laser element 10 can be stably operated. The optical detection element 20 is disposed at the position adjacent to the wavelength tunable laser element 10 and the temperature detection element 18, and hence the elements in the inside of the optical module 1 can be compactly disposed. Thus, the elements are compactly disposed, and hence a reduction in the size of the optical module 1 can be achieved.

The optical detection element 20 is made up of a silicon-based semiconductor material. Therefore, the optical detection element 20 is disposed at the position adjacent to the wavelength tunable laser element 10 and the temperature detection element 18. Thus, the deviation between the temperatures is restrained, and the variation in the characteristics of the refractive index of silicon in the optical detection element 20 can be reduced. Therefore, even though the optical detection element 20 and the wavelength tunable laser element 10 are disposed on one TEC 33, the wavelength tunable laser element 10 can be stably operated.

The wavelength tunable laser element 10 is obliquely disposed such that the wavelength tunable laser element 10 is directed to the temperature detection element 18 side to the optical axis of the laser light beam L1. Therefore, the wavelength tunable laser element 10 is obliquely disposed to the optical axis of the laser light beam L1, and hence the laser light beam L can be restrained from returning to the wavelength tunable laser element 10 due to reflection. The wavelength tunable laser element 10 is obliquely inclined to the temperature detection element 18 side, and hence the wavelength tunable laser element 10 can be brought close to the temperature detection element 18. Thus, the temperature management of the wavelength tunable laser element 10 can be more appropriately performed. Therefore, the wavelength tunable laser element 10 can be further stably operated.

The optical module 1 includes the beam splitter 15 that directs the laser light beam L output from the wavelength tunable laser element 10 to the direction opposite to the output direction of the laser light beam L1. Therefore, the laser light beam L1 output from the wavelength tunable laser element 10 is directed to the direction opposite to the output direction by the beam splitter 15. The laser light beam L1 is directed to the direction opposite to the output direction, and hence the region occupied by the optical path of the laser light beam in the inside of the optical module 1 can be made small. Thus, the optical module 1 can be further reduced in size. The laser light beam L3 directed to the opposite direction by the beam splitter 15 is input to the optical detection element 20, and hence the optical detection element 20 can be disposed at the position adjacent to the wavelength tunable laser element 10. As described above, the position of the optical detection element 20 can be brought close to the position of the wavelength tunable laser element 10.

The optical module 1 includes the isolator 14 located between the wavelength tunable laser element 10 and the beam splitter 15. Therefore, the vacant region S2 between the wavelength tunable laser element 10 and the beam splitter 15 can be effectively used as a region where the isolator 14 is disposed. The optical module 1 includes the optical output port 3, and includes the beam shifter 16 located between the optical output port 3 and the beam splitter 15. Therefore, the vacant region S1 between the optical output port 3 and the beam splitter 15 can be effectively used as a region where the beam shifter 16 is disposed. As described above, the vacant regions S1 and S2 in the inside of the optical module 1 can be effectively used as regions where elements are mounted, and hence this contributes to a further reduction in the size of the optical module 1.

The optical module 1 includes the base 34 mounted with the beam splitter 15 separating from the TEC 33 mounted with the wavelength tunable laser element 10, the temperature detection element 18, and the optical detection element 20. As described above, the base 34 mounted with the beam splitter 15 is included separately from the TEC 33, and hence the TEC 33 can be made small. Therefore, the TEC 33 is reduced in size, and hence the power consumption of the TEC 33 can be reduced.

As described above, the optical module according to the embodiment is described. However, the optical module according to the present application is not limited to the foregoing embodiment, and can be variously modified. That is, the configurations of the components of the optical module can be appropriately modified in the scope of the gist of claims. For example, in the foregoing embodiment, the optical module 1 including the housing 2 having the electrical connecting terminal 4 on the side face 2c is described. However, the position, size, shape, and disposition form of the electrical connecting terminal of the optical module can be appropriately modified.

What is claimed is:

1. An optical module, comprising:
an LD that emits laser beam;
a carrier that mounts the LD and thermistor thereon;
a photodetector detecting the laser beam output from the LD;
a TEC that mounts the carrier and the photodetector thereon;
a chassis having a box-shape demarcated by walls that form a space for enclosing the LD, the TEC, and the photodetector therein,
wherein at least of the walls has a window, and the thermistor arranged between the LD and the photodetector.

2. The optical module of claim 1
wherein the photodetector composed of a material including a silicon

3. The optical module of claim 1
further comprising a beam splitter input the laser beam, and output a first output beam and a second output beam opposite to the first output beam.

4. The optical module of claim 3
further comprising an isolator arranged between the LD and the beam splitter.

5. The optical module of claim 1
wherein the photodetector includes a 90-degree hybrid, a first light receiving element, a second light receiving element, a third light receiving element.

6. The optical module of claim 1
wherein the LD being a wavelength tunable laser.

7. The optical module of claim 6
wherein the wavelength tunable laser includes a Sampled Grating Distributed FeedBack, a Chirped Sampled Grating Distributed Bragg Reflector, and a Semiconductor Optical Amplifier.

8. The optical module of claim 7
wherein at least of the Sampled Grating Distributed FeedBack and the Chirped Sampled Orating Distributed Bragg Reflector being a heater.
